(19) United States
(12) Patent Application Publication
(10) Pub. No.: US 2006/0049852 A1
(43) Pub. Date: Mar. 9, 2006

(54) Sense amplifier with low common mode differential input signal

(76) Inventors: In-Soo Park, Suwon-Si (KR); Kyu-Hyoun Kim, Suwon-Si (KR)

Correspondence Address: LAW OFFICE OF MONICA H CHOI, P O BOX 3424, DUBLIN, OH, 430160204, US

(21) Appl. No.: 11/220,180

(22) Filed: Sep. 6, 2005

(30) Foreign Application Priority Data
Sep. 9, 2004 (KR) 2004-72214

(51) Int. Cl. H03F 3/45

(52) U.S. Cl. 327/55

(57) ABSTRACT

A sense amplifier includes a first amplifier with differential input devices and load inverters for the differential input devices with the load inverters being cross-coupled in a latching configuration. The sense amplifier also includes a second amplifier coupled to the first amplifier, and the second amplifier includes latching inverters cross-coupled in a latching configuration. The double inverter latching action in the first and second amplifiers enhances response speed even with a low common mode reference voltage.

### BACKGROUND OF THE INVENTION

This application claims priority to Korean Patent Application No. 2004-72214, filed on Sep. 9, 2004, in the Korean Intellectual Property Office, the disclosure of which is incorporated herein in its entirety by reference.

1. Field of the Invention

The present invention relates generally to sense amplifiers, and more particularly, to a sense amplifier having enhanced response time even with a low common mode differential input signal.

2. Description of the Related Art

A sense amplifier is commonly used in semiconductor devices, especially semiconductor memory devices. The sense amplifier senses and amplifies a voltage difference between two differential input signals to generate differential output signals. Small portable electronic devices such as a mobile phone are desired to be operated at low voltages with minimum power dissipation. Thus, a sense amplifier within such a portable electronic device is desired to operate stably and fast even at a low voltage.

FIG. 1 is a circuit diagram of a conventional sense amplifier including PMOS (P-channel metal oxide semiconductor) transistors P1, P2, P3, P4, and P5, and NMOS (N-channel metal oxide semiconductor) transistors N1, N2, N3, N4, and N5. The sense amplifier of FIG. 1 is a differential sense amplifier having one IN+ of the differential input signals swinging with respect to a reference voltage VREF applied as the other IN− of the differential input signals. FIG. 2 illustrates the waveforms of the reference voltage VREF and the input signal IN+.

When the input signal IN+ is at a logic high level, that is, when the level of the input signal IN+ is greater than the reference voltage VREF, the NMOS transistor N3 is turned on to begin the sensing operation of the sense amplifier. When the input signal IN+ is at a logic low level, that is, when the level of the input signal IN+ is less than the reference voltage VREF, the NMOS transistor N3 is turned off, and the NMOS transistor N4 is turned on to start the sensing operation of the sense amplifier.

However, in a low common mode, i.e., when the reference voltage VREF is low, the NMOS transistor N4 is slightly turned on, and thus, generation of the differential output signals at the output nodes V1 and V2 is delayed when a clock signal CLK is at a logic high level. In other words, when the input signal IN+ is at a logic low level, the sensing speed of the sense amplifier is reduced. Further, the high/low (high to low transition) skew of data output from the sense amplifier is increased.

### SUMMARY OF THE INVENTION

Accordingly, a sense amplifier of embodiments of the present invention is implemented with double inverter latching action for enhanced response speed even with a low common mode reference voltage.

In one embodiment of the present invention, the sense amplifier includes a first amplifier with differential input devices and load inverters for the differential input devices. The load inverters in the first amplifier are cross-coupled in a latching configuration. The sense amplifier also includes a second amplifier coupled to the first amplifier, and the second amplifier includes latching inverters cross-coupled in a latching configuration.

In an embodiment of the present invention, an output node of a first load inverter forms a first output node of the first amplifier, and an output node of a second load inverter forms a second output node of the first amplifier. The differential input devices include differentially coupled first and second NMOSFETs (N-channel Metal Semiconductor Field Effect Transistors). The first load inverter is comprised of a PMOSFET (P-channel Metal Semiconductor Field Effect Transistors) and an NMOSFET (N-channel Metal Semiconductor Field Effect Transistors) coupled as an inverter with a source of the NMOSFET of the first load inverter being coupled to a drain of the differentially coupled first NMOSFET. The second load inverter is comprised of a PMOSFET and an NMOSFET coupled as an inverter with a source of the NMOSFET of the second load inverter being coupled to a drain of the differentially coupled second NMOSFET.

In a further embodiment of the present invention, the latching inverters are coupled between the first and second output nodes of the first amplifier. For example, the second amplifier is comprised of a first latching inverter and a second latching inverter. The first latching inverter has an output coupled to the first output node and an input coupled to the second output node, and the second latching inverter has an output coupled to the second output node and an input coupled to the first output node.

In another embodiment of the present invention, the sense amplifier further includes an equalizing device for coupling together the first and second output nodes in response to a clock signal. In a further embodiment of the present invention, the sense amplifier also includes pull-up devices for coupling the first and second output nodes to a voltage source in response to the clock signal.

In yet another embodiment of the present invention, the sense amplifier includes a first activating circuit and a second activating circuit. The first activating circuit is coupled to the first amplifier for activating an amplifying operation of the first amplifier in response to the clock signal. The second activating circuit is coupled to the second amplifier for activating an amplifying operation of the second amplifier in response to the clock signal.

In a further embodiment of the present invention, a common mode reference voltage is input by one of the differential input devices of the first amplifier. In that case, a voltage input by the other of the differential input devices of the first amplifier swings about the common mode reference voltage.

In this manner, both of the first and second amplifiers include inverters coupled in a latching configuration. With such double inverter latching action by the first and second amplifiers, the response speed for generating the differential output signals by the sense amplifier is enhanced even for a low common mode reference voltage.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a conventional sense amplifier;

FIG. 2 illustrates waveforms of a reference voltage and an input signal for the sense amplifier; and

FIG. 3 is a circuit diagram of a sense amplifier according to an embodiment of the present invention.

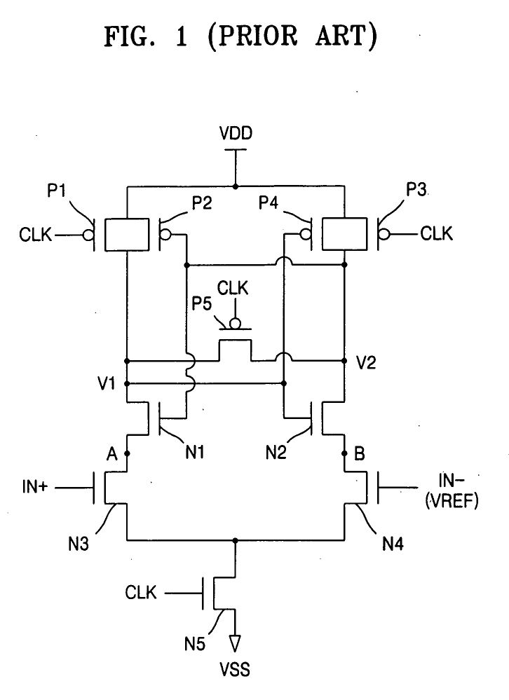

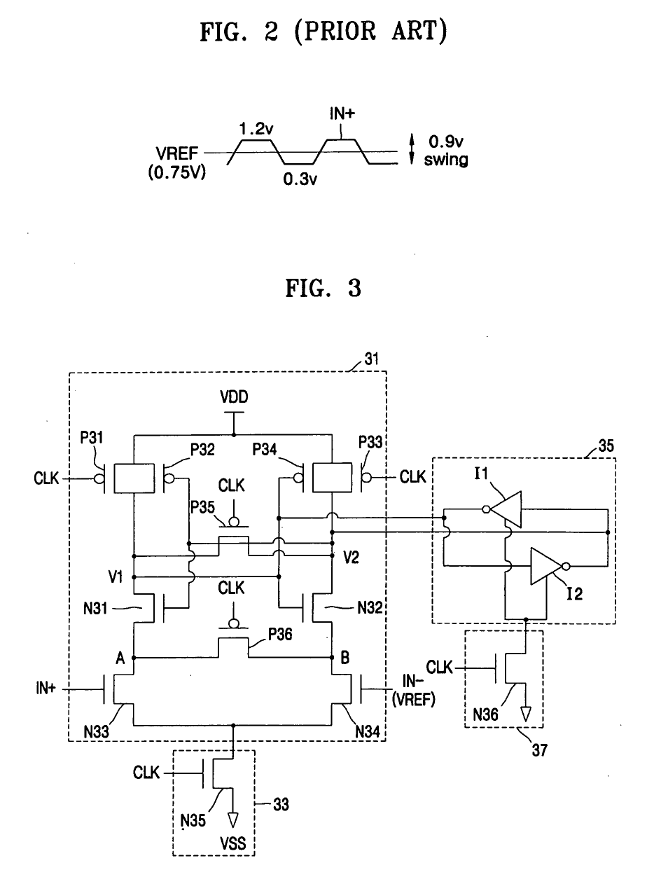

The figures referred to herein are drawn for clarity of illustration and are not necessarily drawn to scale. Elements having the same reference number in FIGS. 1, 2, and 3 refer to elements having similar structure and/or function.

### DETAILED DESCRIPTION OF THE INVENTION

FIG. 3 is a circuit diagram of a sense amplifier according to an embodiment of the present invention. The sense amplifier is a differential sense amplifier that has one IN+ of the differential input signals swinging with respect to a reference voltage VREF applied as the other IN− of the differential input signals. Referring to FIG. 3, the sense amplifier includes a first amplifier 31, a first activating circuit 33, a second amplifier 35, and a second activating circuit 37.

The first amplifier 31 receives a first differential input signal IN+ and a second differential input signal IN−, and senses and amplifies the voltage difference between such differential input signals IN+ and IN− to generate differential output signals at first and second output nodes V1 and V2. The second differential input signal IN− is a common mode reference voltage VREF maintained at a constant level. The first activating circuit 33 is coupled to the first amplifier 31 to activate the first amplifier 31 to perform the amplifying operation in response to a clock signal CLK (i.e., when the clock signal CLK is activated to a logical high).

The second amplifier 35 is an auxiliary sensing circuit for enhancing the sensing operation of the sense amplifier. The second amplifier 35 is coupled between the first and second output nodes V1 and V2 of the first amplifier 31 to further amplify and latch the differential output signals at the first and second output nodes V1 and V2. The second activating circuit 37 is coupled to the second amplifier 35 to activate the second amplifier 35 to perform the amplifying operation in response to the clock signal CLK (i.e., when the clock signal CLK is activated to a logical high).

The first amplifier 31 includes first, second, third, fourth, fifth, and sixth PMOSFETs (P-channel metal oxide semiconductor field effect transistors) P31, P32, P33, P34, P35, and P36, respectively. The first amplifier 31 also includes first, second, third, and fourth NMOSFETs (N-channel metal oxide semiconductor field effect transistors) N31, N32, N33, and N34, respectively.

A source of the first PMOSFET P31 is coupled to a supply voltage VDD, a gate of the first PMOSFET P31 is coupled to the clock signal CLK, and a drain of the first PMOSFET P31 is coupled to the first output node V1. A source of the second PMOSFET P32 is coupled to the supply voltage VDD, a gate of the second PMOSFET P32 is coupled to a gate of the first NMOSFET 31 and the second output node V2, and a drain of the second PMOSFET P32 is coupled to the first output node V1.

A source of the third PMOSFET P33 is coupled to a supply voltage VDD, a gate of the third PMOSFET P33 is coupled to the clock signal CLK, and a drain of the third PMOSFET P33 is coupled to the second output node V2. A source of the fourth PMOSFET P34 is coupled to the supply voltage VDD, a gate of the fourth PMOSFET P34 is coupled to a gate of the second NMOSFET 32 and the first output node V1, and a drain of the fourth PMOSFET P34 is coupled to the second output node V2.

The fifth PMOSFET P35 is coupled between the first and second output nodes V1 and V2, and a gate of the fifth PMOSFET P35 is coupled to the clock signal CLK. The sixth PMOSFET P36 is coupled between a source A of the first NMOSFET N31 and a source B of the second NMOSFET N32, and a gate of the sixth PMOSFET P36 is coupled to the clock signal CLK.

A drain of the first NMOSFET N31 is coupled to first output node V1, and a gate of the first NMOSFET N31 is coupled to the second output node V2. A drain of the second NMOSFET N32 is coupled to second output node V2, and a gate of the second NMOSFET N32 is coupled to the first output node V1.

A drain of the third NMOSFET N33 is coupled to the source A of the first NMOSFET N31, a gate of the third NMOSFET N33 is coupled to the first differential input signal IN+, and a source of the third NMOSFET N3 is coupled to the first activating circuit 33. A drain of the fourth NMOSFET N34 is coupled to the source B of the second NMOSFET N32, a gate of the fourth NMOSFET transistor N34 is coupled to the second differential input signal IN− (i.e., the common mode reference voltage VREF), and a source of the fourth NMOSFET N34 is coupled to the first activating circuit 33.

In this manner, the third and fourth NMOSFETs N33 and N34 form differential input devices for inputting the differential input signals IN+ and IN−. In addition, the second PMOSFET P32 and the first NMOSFET N31 having their gates coupled together and their drains coupled together form a first load inverter for the third NMOSFET N33. Similarly, the fourth PMOSFET P34 and the second NMOSFET N32 having their gates coupled together and their drains coupled together form a second load inverter for the fourth NMOSFET N34. Furthermore, note that such load inverters are coupled in a latching configuration with the input of the first load inverter being coupled to the output of the second load inverter and with the input of the second load inverter being coupled to the output of the first load inverter.

The first activating circuit 33 includes an NMOSFET 35 having a drain coupled to the first amplifier 31, a gate with the clock signal CLK applied thereon, and a source with a ground voltage VSS applied thereon.

The second amplifier 35 is a latch type amplifier with first and second latching inverters I1 and I2. The first latching inverter I1 has an output coupled to the first output node V1 of the first amplifier 31, and has an input coupled to the second output node V2 of the first amplifier 31. The second latching inverter I2 has an input coupled to the first output node V1, and has an output coupled to the second output node V2. In addition, the first and second latching inverters I1 and I2 are coupled in a latching configuration with the input of the first latching inverter I1 being coupled to the output of the second latching inverter I2, and with the output of the first latching inverter I1 being coupled to the input of the second latching inverter I2.

The second activating circuit 37 includes an NMOSFET N36 having a drain connected to the second amplifier 35, a gate with the clock signal CLK applied thereon, and a source with a ground voltage VSS applied thereon.

During operation of the sense amplifier of FIG. 3, the first and third PMOSFETs P31 and P33 form pull-up devices that turn on in response to the CLK signal to pull-up the output nodes V1 and V2 to the high supply voltage VDD. In addition, the fifth and sixth PMOSFETs P35 and P36 form equalizing devices that turn on in response to the CLK signal to couple the output nodes V1 and V2 together during an equalization operation.

When the first, third, fifth, and sixth PMOSFETs P31, P33, P35, and P36 are turned off in response to the CLK signal, the NMOSFETs N35 and N36 in the first and second activating circuits 33 and 37 are turned on in response to the CLK signal for activating the sensing and amplifying operation of the first and second amplifiers 31 and 35.

During such a sensing and amplifying operation, the fourth NMOSFET N34 is slightly turned on when the input signal IN⁺ is at a logic low level, i.e., when the level of the input signal IN+ is less than the reference voltage VREF, and when the reference voltage VREF is relatively low. Without dual latching action in the first and second amplifiers 31 and 35, a speed that a voltage at the source B of the second NMOS transistor N32 is reduced to the ground voltage VSS would be lowered, and thus, transition of data at the output nodes V1 and V2 would be delayed. As a result, the sensing speed of the sense amplifier would be reduced and the high to low skew of output data would be increased.

However, in the sense amplifier of FIG. 3 according to the present invention, the first amplifier 31 includes the load inverters (formed by MOSFETs P32, N31, P34, and N32) coupled in a latching configuration, and the second amplifier 35 includes the latching inverters I1 and I2 coupled in a latching configuration. Such dual latching action in the first and second amplifiers 31 and 35 allows for high-speed transition of the differential output signals at the output nodes V1 and V2 even with slow transition of the voltage at the node B to the ground voltage VSS. Accordingly, the speed of sensing logic low input data at the input node IN+ is enhanced for reduced high to low skew of output data even when the common mode reference voltage VREF applied at the other input node IN− is relatively low.

While this invention has been particularly shown and described with reference to exemplary embodiments thereof, it will be understood by those skilled in the art that various changes in form and details may be made therein without departing from the spirit and scope of the invention as defined by the appended claims.

What is claimed is:

1. A sense amplifier comprising:
a first amplifier including differential input devices and load inverters for the differential input devices, wherein the load inverters are cross-coupled in a latching configuration; and
a second amplifier coupled to the first amplifier, the second amplifier including latching inverters cross-coupled in a latching configuration.

2. The sense amplifier of claim 1, wherein an output node of a first load inverter forms an first output node of the first amplifier, and wherein an output node of a second load inverter forms a second output node of the first amplifier.

3. The sense amplifier of claim 2, wherein the differential input devices include differentially coupled first and second NMOSFETs (N-channel Metal Semiconductor Field Effect Transistors).

4. The sense amplifier of claim 3, wherein the first load inverter is comprised of a PMOSFET (P-channel Metal Semiconductor Field Effect Transistors) and an NMOSFET (N-channel Metal Semiconductor Field Effect Transistors) coupled as an inverter with a source of the NMOSFET of the first load inverter being coupled to a drain of the differentially coupled first NMOSFET.

5. The sense amplifier of claim 4, wherein the second load inverter is comprised of a PMOSFET (P-channel Metal Semiconductor Field Effect Transistors) and an NMOSFET (N-channel Metal Semiconductor Field Effect Transistors) coupled as an inverter with a source of the NMOSFET of the second load inverter being coupled to a drain of the differentially coupled second NMOSFET.

6. The sense amplifier of claim 2, wherein the latching inverters are coupled between the first and second output nodes of the first amplifier.

7. The sense amplifier of claim 6, wherein the second amplifier is comprised of:
a first latching inverter having an output coupled to the first output node and an input coupled to the second output node; and
a second latching inverter having an output coupled to the second output node and an input coupled to the first output node.

8. The sense amplifier of claim 2, further comprising:
an equalizing device for coupling together the first and second output nodes in response to a clock signal.

9. The sense amplifier of claim 2, further comprising:
pull-up devices for coupling the first and second output nodes to a voltage source in response to a clock signal.

10. The sense amplifier of claim 1, further comprising:
a first activating circuit coupled to the first amplifier for activating an amplifying operation of the first amplifier in response to a clock signal.

11. The sense amplifier of claim 1, further comprising:
a second activating circuit coupled to the second amplifier for activating an amplifying operation of the second amplifier in response to a clock signal.

12. The sense amplifier of claim 1, wherein a common mode reference voltage is input by one of the differential input devices of the first amplifier.

13. A method for amplifying differential input signals, comprising:
amplifying the differential input signals with load inverters cross-coupled in a latching configuration to generate differential output signals; and
amplifying the differential output signals with latching inverters cross-coupled in a latching configuration.

14. The method of claim 13, further comprising:
activating the amplifying of the differential input signals in response to a clock signal.

15. The method of claim 13, further comprising:
activating the amplifying of the differential output signals in response to a clock signal.

16. The method of claim 13, further comprising:
applying a common mode reference voltage as one of the differential input signals.

17. The method of claim 13, further comprising:
generating the differential output signals at first and second output nodes; and
coupling together the first and second output nodes for equalization in response to a clock signal.

18. The method of claim 13, further comprising:
generating the differential output signals at first and second output nodes; and
coupling the first and second output nodes to a voltage source for a pull-up operation in response to a clock signal.

19. A sense amplifier comprising:
means for amplifying differential input signals with load inverters cross-coupled in a latching configuration to generate differential output signals; and
means for amplifying the differential output signals with latching inverters cross-coupled in a latching configuration.

20. The sense amplifier of claim 19, further comprising:
means for activating the amplifying of the differential input signals and the differential output signals in response to a clock signal.
